(19) United States
(12) Patent Application Publication
(10) Pub. No.: US 2025/0344606 A1
(43) Pub. Date: Nov. 6, 2025

(54) NANOPOSITIONER AND PIEZOELECTRIC ACTUATOR

(71) Applicant: RENAISSANCE SCIENTIFIC, INC., Superior, CO (US)

(72) Inventors: Ryan Murdick, Superior, CO (US); Daniel Svenkeson, Collins, CO (US)

(21) Appl. No.: 18/997,864

(22) PCT Filed: Aug. 4, 2023
(86) PCT No.: PCT/US2023/029457

§ 371 Date: Jan. 23, 2025

Related U.S. Application Data
(60) Provisional application No. 63/396,296, filed on Aug. 9, 2022.

(51) Int. Cl. H10N 30/88; H10N 30/50; H10N 30/87

(52) U.S. Cl. CPC H10N 30/88; H10N 30/50; H10N 30/87

(57) ABSTRACT

A nanopositioner 10 including a base 12 including a base plate 18 carrying a set of base bearings 22, a carrier 14 movably carried with respect to the base 12 and including a carrier plate 56 carrying a set of carrier bearings 58 operatively coupled to the set of base bearings 22. The nanopositioner 10 may include a variable area capacitive position sensor, and/or an actuator 16 operatively coupling the carrier 14 to the base 12 and including an armature 100 fixed with respect to the carrier 14 and a stator 98 removably coupled to the base 12 to facilitate removal and replacement of at least a portion of the stator 98. Also disclosed are a method of producing a nanopositioner, and a piezoelectric actuator 16 that may be used with a nanopositioner.

### TECHNICAL FIELD

This disclosure relates generally to positioning devices and, more particularly, to nanopositioners.

### BACKGROUND

Nanopositioners are used in many applications including, for example, in scanning probe microscopes and in cryogenic research equipment. In room-temperature environments, nanopositioners move samples under observation over a typical range of motion of several millimeters, with step sizes as low as one nanometer, albeit with significant step-to-step variation on the order of 30-50%. Nanopositioners are also referred to as motors and typically include slip-stick (or stick-slip) piezoelectric actuators that provide a motive force according to a slip-stick cycle. The cycle has a slow ramp wherein a piezoelectric drive element of the motor sticks to, or remains in contact with, a driven element of the motor, and also has a fast ramp wherein the piezoelectric drive element slips from, or breaks contact with respect to, the driven element. Reversal in direction of the driven element is achieved via an anti-symmetric power waveform applied to the piezoelectric drive element. Nanopositioners and piezoelectric actuators have been known and used for decades with much success, particularly in ambient temperature environments.

In cryogenic environments, however, nanopositioners and piezoelectric actuators are a challenge to implement successfully. Currently available nanopositioners operate with relatively low voltages on the order of 30 to 70 volts and relatively high currents on the order of 10s of milliamps, with positional repeatability on the order of two microns. But those nanopositioners use relatively large piezo stacks that operate with relatively high capacitances on the order of 5 to 10 microfarads that generate an undesirable amount of heat in a cryogenic environment. And many piezoelectric actuators are prone to premature wear that may be attributable to electrical arcing. But the present inventor discovered a simple and elegant solution in the form of the presently disclosed nanopositoner that may produce significantly less heat than conventional nanopositioners and also may increase positional repeatability, and/or in the form of the presently disclosed piezoelectric actuator that may be resistant to premature wear, or wear that occurs in the normal course of a lifetime of a piezoelectric actuator, as discussed below.

### SUMMARY

An illustrative embodiment of a nanopositioner includes a base including a base plate having a base bottom with a bottom surface, and a base top with a position driver mounting surface, and base bearing mounting surfaces outboard of the position driver mounting surface, and an actuator aperture extending between the bottom surface and the position driver mounting surface. The nanopositioner also includes a position driver carried by the position driver mounting surface of the top of the base plate and including set of drive electrodes, and a set of base bearings carried by the base bearing mounting surfaces of the top of the base plate. The nanopositioner further includes a carrier movably carried with respect to the base and including a carrier plate having a top with a top surface, and a bottom with a position receiver mounting surface corresponding to and facing the position driver mounting surface of the top of the base plate of the base, and carrier bearing mounting surfaces outboard of the position receiver mounting surface. The nanopositioner additionally includes a position receiver carried by the position receiver mounting surface of the bottom of the carrier plate and including a sense electrode operatively coupled to the set of drive electrodes, and a set of carrier bearings carried by the carrier bearing mounting surfaces of the bottom of the carrier plate and operatively coupled to the set of base bearings. The nanopositioner moreover includes an actuator operatively coupling the carrier to the base and including a stator removably coupled to the base to facilitate removal and replacement of at least a portion of the stator, and an armature operatively coupled to the stator, extending through the actuator aperture of the base plate of the base, and coupled to the carrier. The sense electrode and the set of drive electrodes at least partially establish a variable area capacitive position sensor.

Another illustrative embodiment of a nanopositioner includes a base including a base plate including an actuator aperture therethrough, a position driver carried by the base plate and including a set of drive electrodes, and a set of base bearings carried by the base plate. The nanopositioner also includes a carrier movably carried with respect to the base and including a carrier plate, a position receiver carried by the carrier plate and including a sense electrode operatively coupled to the set of drive electrodes, and a set of carrier bearings carried by the carrier plate and operatively coupled to the set of base bearings. The nanopositioner further includes an actuator operatively coupling the carrier to the base and including an armature fixed with respect to the carrier, and a stator removably coupled to the base to facilitate removal and replacement of at least a portion of the stator.

A further illustrative embodiment of a nanopositioner includes a base including a base plate including an actuator aperture therethrough, a position driver carried by the base plate and including a set of drive electrodes, and a set of base bearings carried by the base plate. The nanopositioner also includes a carrier movably carried with respect to the base and including a carrier plate, a position receiver carried by the carrier plate and including a sense electrode operatively coupled to the set of drive electrodes, and a set of carrier bearings carried by the carrier plate and operatively coupled to the set of base bearings. The nanopositioner further includes an actuator operatively coupling the carrier to the base and including a stator fixed with respect to the base, and an armature operatively coupled to the stator, extending through the actuator aperture of the base plate of the base, and coupled to the carrier.

An additional illustrative embodiment of a nanopositioner includes a base including a base plate including an actuator aperture therethrough, a position driver carried by the base plate and including a set of drive electrodes, and a set of base bearings carried by the base plate. The nanopositioner also includes a carrier movably carried with respect to the base and including a carrier plate, a position receiver carried by the carrier plate and including a sense electrode operatively coupled to the set of drive electrodes, and a set of carrier bearings carried by the carrier plate and operatively coupled to the set of base bearings. The sense electrode and the set of drive electrodes at least partially establish a variable area capacitive position sensor.

An illustrative embodiment of a method of producing a nanopositioner includes: processing top and bottom surfaces of a base plate to be parallel to each other within a base plate tolerance; processing top and bottom surfaces of a carrier plate to be parallel to each other within a carrier plate tolerance; mounting an actuator armature to the bottom surface of the carrier plate; processing a bottom surface of a platform of the armature to be parallel to the top surface of the carrier plate within an armature tolerance; removing the actuator armature from the carrier plate; mounting a position receiver to the bottom surface of the carrier plate; mounting position drive board standoffs to the top surface of the base plate; mounting a position drive board onto the standoffs on the top surface of the base plate; measuring parallelism of the position drive board to obtain parallelism measurements of the drive board; and processing top surfaces of the drive board standoffs using the parallelism measurements so that a top surface of the drive board is parallel to the bottom surface of the base plate within a drive board tolerance.

An illustrative embodiment of a piezoelectric stack includes a primary piezoelectric element having primary opposite faces and primary sides extending between the primary opposite faces, a secondary piezoelectric element having secondary opposite faces and secondary sides extending between the secondary opposite faces, and a conductive foil disposed between facing faces of the primary and secondary opposite faces of the primary and secondary piezoelectric elements, and having at least one tab extending laterally outwardly with respect to at least one of the primary sides and at least one of the secondary sides.

### BRIEF DESCRIPTION OF THE DRAWINGS

FIG. 1 is a rear upper perspective view according to an illustrative embodiment of a nanopositioner.

FIG. 2 is an exploded elevational view of the nanopositioner of FIG. 1 that includes an embodiment of a base, an embodiment of a carrier configured to be movably carried by the base, and an embodiment of an actuator configured to movably couple the carrier with respect to the base.

FIG. 3 is a top view of an embodiment of a base plate of the base of FIG. 2.

FIG. 4 is an end view of the base plate of FIG. 3.

FIG. 5 is a top view of an embodiment of a position drive board of the base of FIG. 2.

FIG. 6 is a side view of the position drive board of FIG. 5.

FIG. 7 is a side view of the base plate of FIG. 3 and an embodiment of position drive board standoffs carried on the base plate.

FIG. 8 is a side view of an embodiment of a base subassembly including the base plate and position drive board standoffs of FIG. 7 and the position drive board of FIG. 5 carried on the position drive board standoffs.

FIG. 9 is a perspective view of the base subassembly of FIG. 8.

FIG. 10 is a top view of an embodiment of a carrier plate of the carrier of FIG. 2.

FIG. 11 is an end view of the carrier plate of FIG. 10.

FIG. 12 is a bottom view an embodiment of another carrier subassembly including the carrier plate of FIG. 10 and a position receiver carried by the carrier plate.

FIG. 13 is an end view of the position receiver of FIG. 12 including a sense electrode carried by a guard electrode.

FIG. 14 is a bottom view of the position receiver of FIG. 12 including the sense electrode surrounded by a portion of the guard electrode.

FIG. 15 is a schematic sectional view through the position receiver of FIG. 12 and illustrating the guard electrode having a central coaxial shield and the sense electrode having a central coaxial conductor extending through the central coaxial shield.

FIG. 16 is a top view of the carrier subassembly of FIG. 12.

FIG. 17 is a top view of the carrier subassembly of FIG. 16 and showing a sensor cable coupled to the position receiver.

FIG. 18 is a perspective view of an embodiment of a frame of an armature of the actuator of FIG. 2.

FIG. 19 is an end view of the frame of FIG. 18.

FIG. 20 is an exploded perspective view of an embodiment of a carrier subassembly including the armature frame of FIG. 18 and the carrier plate of FIG. 10.

FIG. 21 is an end view of the carrier subassembly of FIG. 20, shown with legs of the armature frame doweled to the carrier plate.

FIG. 22 is a front upper exploded perspective view of the nanopositioner of FIG. 1, illustrating the carrier movably coupled to the base, the armature configured to be fixed to the carrier, and the stator configured to be fastened to the base to movably trap the armature with respect to the base and including a piezoelectric actuator.

FIG. 23 is an end view of the nanopositioner of FIG. 1.

FIG. 24 is a front upper perspective view of the nanopositioner of FIG. 1, showing bearing positioners coupled to the carrier.

FIG. 25 is a perspective sectional view of the nanopositioner of FIG. 1 taken through legs of the armature frame and through a portion of the stator to illustrate the closed loop mechanical and instrumented connection of the carrier to the base via the actuator and a variable area capacitive position sensor including the position driver and the position receiver.

FIG. 26 is a perspective sectional view of the nanopositioner of FIG. 1 taken longitudinally centrally therethrough.

FIG. 27 is a top view of an embodiment of a preload plate of the piezoelectric actuator of FIG. 22.

FIG. 28 is a top view of an embodiment of a base or primary piezoelectric element carried in a pocket of the preload plate of FIG. 27.

FIG. 29 is a top view of an embodiment of a foil carried on the piezoelectric element of FIG. 28.

FIG. 30 is a top view of an embodiment of a secondary piezoelectric element carried on the foil of FIG. 29.

FIG. 31 is a top view of an embodiment of a sliding bearing element carried on the secondary piezoelectric element of FIG. 30.

FIG. 32 is a schematic side view of an embodiment of the piezoelectric actuator of FIG. 22.

FIG. 33 is an electrical schematic side view of an embodiment of the piezoelectric actuator of FIG. 22, shown in a state of rest.

FIG. 34 is an electrical schematic side view of an embodiment of the piezoelectric actuator of FIG. 22, shown in an energized state.

### DETAILED DESCRIPTION

In general, an apparatus will be described using one or more examples of illustrative embodiments of a nanopositioner that includes one or more examples of illustrative embodiments of a piezoelectric actuator. The example embodiments will be described with reference to use in a cryogenic environment. However, it will be appreciated as the description proceeds that the embodiments are useful in many different applications and may be implemented in many other environments including ambient temperature environments and other non-cryogenic environments.

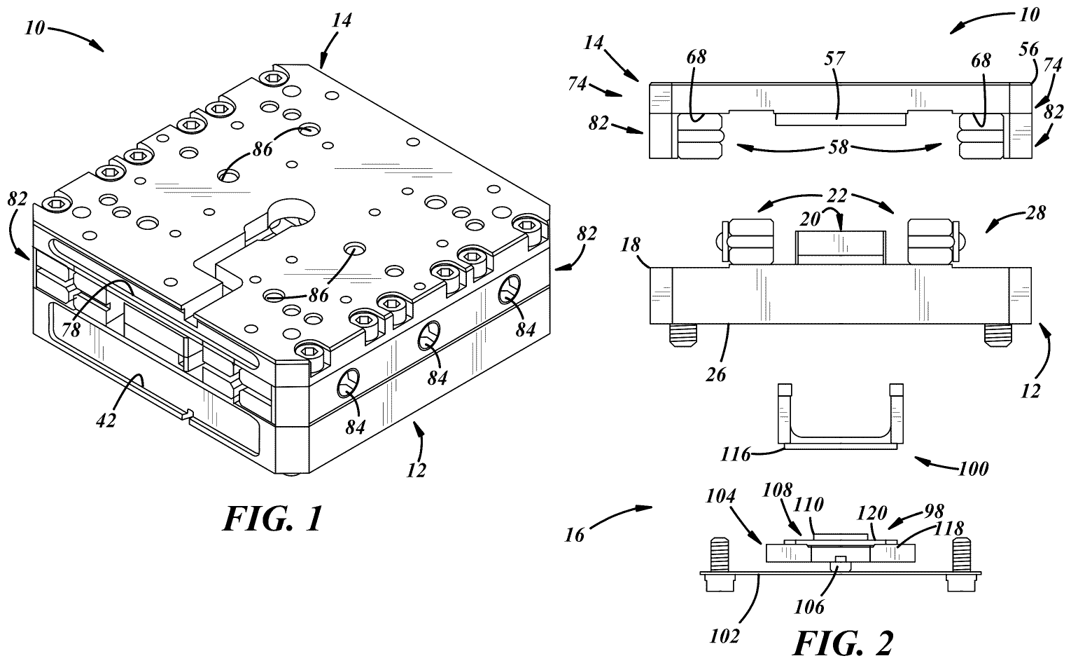

Referring specifically to the drawings, FIG. 1 shows an illustrative embodiment of a nanopositioner 10 that may be used in a cryogenic environment, or in any other environment suitable for use with nanopositioners. The nanopositioner 10 may be driven by a slip-stick piezoelectric actuator, a magnetoresistive actuator, or any other actuator suitable for use with a nanopositioner 10. Externally instrumented nanopositioners, such as those that use interferometric instrumentation external to the nanopositioners, are capable of positional repeatability on the nanometer level, when they work. And conventional internally instrumented nanopositioners, in a cryogenic environment, are oxymoronic in that they are capable of positional repeatability of on the order of two microns, (e.g. 1-3 microns), rendering them mere micropositioners. Notably, internal position instrumentation of conventional nanopositioners typically includes resistive sensing configurations, like reverse potentiometers, to measure position of a carrier relative to a base. In contrast, the presently disclosed nanopositioners may be internally instrumented but are configured to provide positional repeatability on the order of 200 nanometers (e.g., 100-300 nanometers), making them true nanopositioners in a cryogenic environment. As used herein, the term “cryogenic” refers to temperatures on the order of 20 mK to 100 K, but many cryogenic experiments typically are carried out at or around 4 K.

With reference to FIG. 2, the nanopositioner 10 includes a base 12, a carrier 14 movably carried with respect to the base 12, and an actuator 16 operatively coupling the carrier 14 to the base 12. As will be described in further detail below, the nanopositioner 10 also may be internally instrumented with internal position instrumentation operatively carried between the base 12 and the carrier 14. The base 12 may be used to mount the nanopositioner 10 to other devices or equipment, and to support other portions of the nanopositioner 10, like the carrier 14. The carrier 14 may be used to carry sample materials or products, SPM instruments, cryogenic research instruments, or anything else suitable for use with a nanopositioner 10. The actuator 16 moves the carrier 14 with respect to the base 12.

The base 12 includes a base plate 18, a position driver 20 carried by the base plate 18 and that is part of the internal position instrumentation, and a set of base bearings 22 carried by the base plate 18. The base 12 may include a drive portion of the nanopositioner 10 that imposes a motive force on the carrier 14 but remains relatively stationary.

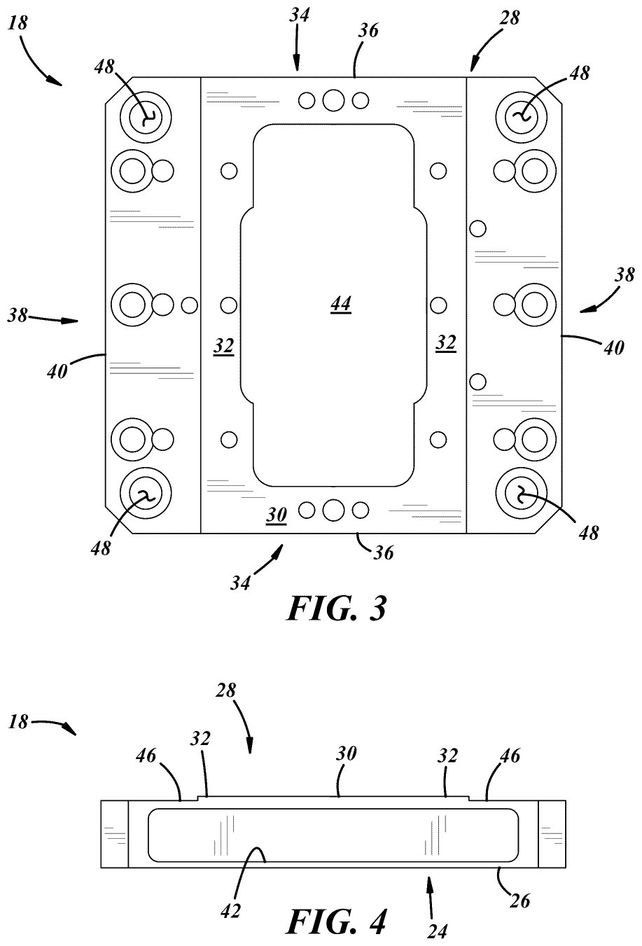

With reference to FIGS. 3 and 4, the base plate 18 may have a base bottom 24 with a bottom surface 26, and a base top 28 with a position driver mounting surface 30, and base bearing mounting surfaces 32 outboard of the position driver mounting surface 30. The base plate 18 also may have base ends 34 with base end surfaces 36 extending between the base bottom 24 and the base top 28, and base sides 38 with base side surfaces 40 extending between the base bottom 24 and the base top 28 and between the base ends 34. The base plate 18 also may include toe clamp pockets 42, for example, in the base end surfaces 36 (see FIG. 4) and/or in the base side surfaces 40, to receive toe clamps (not shown) during production of the base plate 18. The base plate 18 has an actuator aperture 44 therethrough that may extend between the bottom surface 26 and the position driver mounting surface 30. The base plate 18 also may have carrier bearing clearance surfaces 46 outboard of the position driver mounting surface 30 and that may be recessed with respect to the position driver mounting surface 30. The base bearing mounting surfaces 32 may be coplanar with the position driver mounting surface 30. The base plate 18 may be provided with suitable mounting holes 48 that may be threaded, and/or with toe clamps (not shown), to facilitate mounting of the nanopositioner 10. The base plate 18 may be composed of titanium, or any other suitable non-ferrous metal.

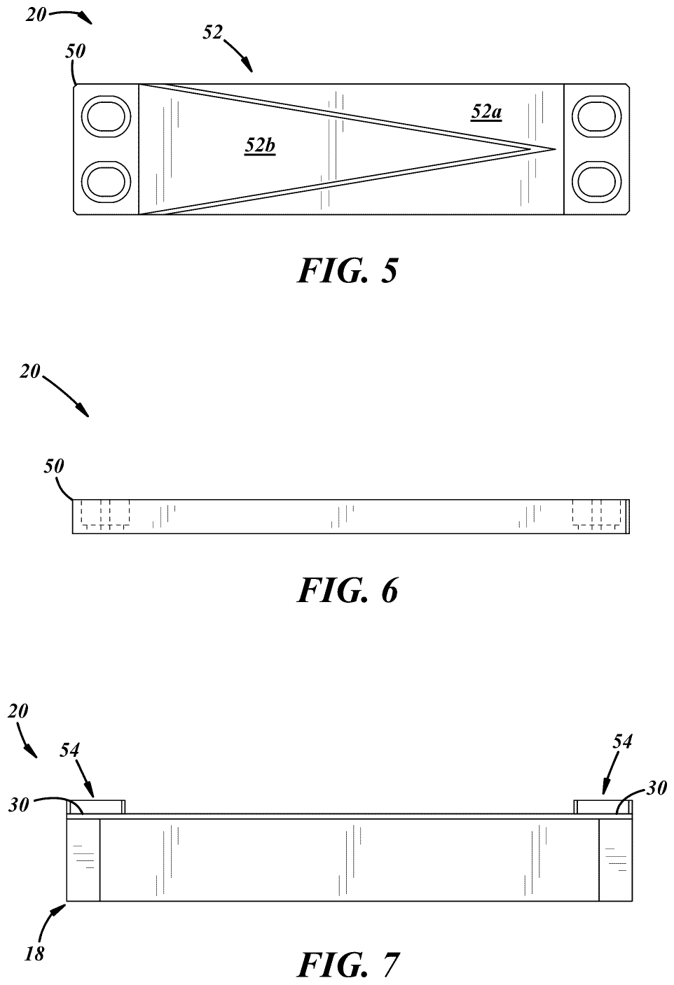

With reference now to FIGS. 5 and 6, the position driver 20 includes a drive board 50 carrying a set of drive electrodes 52. The set of drive electrodes 52 may include complementary, inverse, interdigitated, or otherwise corresponding first and second electrodes 52a,b. The corresponding electrodes may be triangular elements, which may include interdigitated triangular elements, which may include a guidon-shaped element 52a establishing a triangular space and a triangle or triangular-shaped element 52b in the triangular space established by the guidon-shaped element 52a. As used herein, the term “triangular-shaped” includes elements that are predominantly in the shape of a triangle, even if not a perfect triangle. The interdigitated triangular elements may be preferable over use of identical triangular elements with adjacent hypotenuses to account for tilt.

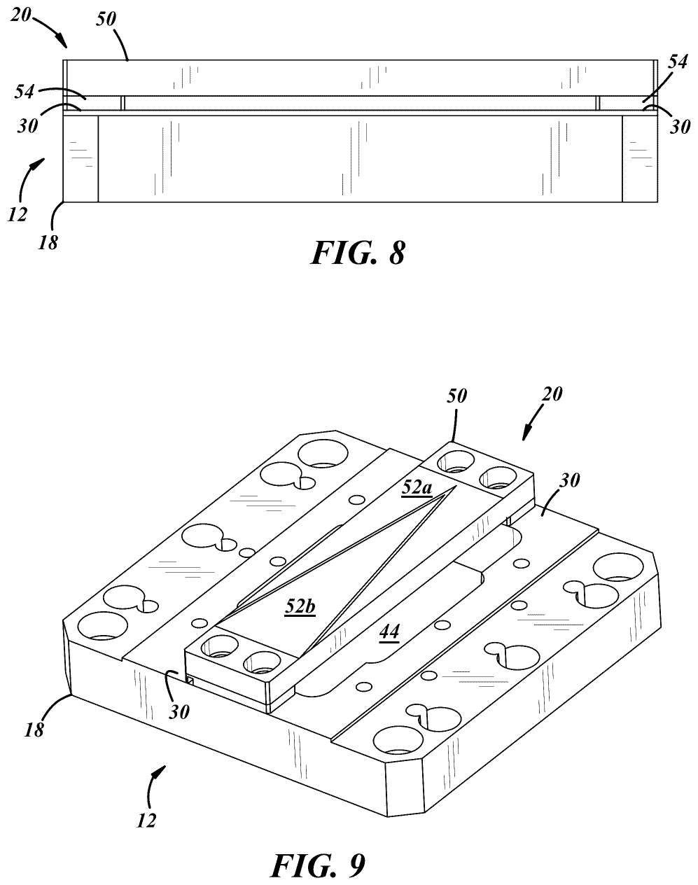

With reference now to FIGS. 7 and 8, the position driver 20 also may include position driver standoffs 54 carrying the position drive board 50 and coupled directly to the position driver mounting surface 30 of the base plate 18. The standoffs 54 may be composed of titanium, or any other suitable non-ferrous metal. With reference again to FIGS. 8 and 9, the position driver 20 may be carried by the position driver mounting surface 30 of the top of the base plate 18, and may include the position drive board 50 bridging over the actuator aperture 44 of the base plate 18 of the base 12. The position drive board 50 may be composed of ceramic or another suitable electrically nonconductive material, and the drive electrodes may be composed of a copper layer on the drive board and a gold layer over the copper layer.

With reference again to FIG. 2, the set of base bearings 22 may be carried by the base bearing mounting surfaces 32 of the top 28 of the base plate 18, and may be carried outboard of the set of drive electrodes 52 (FIG. 5) of the position drive board 50. The set of base bearings 22 may include vee groove rails, ball bearings carried between the vee groove rails, ball retention cages to retain the ball bearings to the vee groove rails, and cage creep stoppers. The vee groove rails may be composed of polished ceramic, zirconia, or the like. The ball retention cages may be composed of polyetheretherketone or any other suitable thermoplastic polymeric material.

With continued reference to FIG. 2, the carrier 14 includes a carrier plate 56, a position receiver 57 carried by the carrier plate 56 and that is another part of the internal position instrumentation, and a set of carrier bearings 58 carried by the carrier plate 56. The carrier 14 may be a driven portion of the nanopositioner 10 that responds to a motive force applied from or via the base 12 and moves in response thereto.

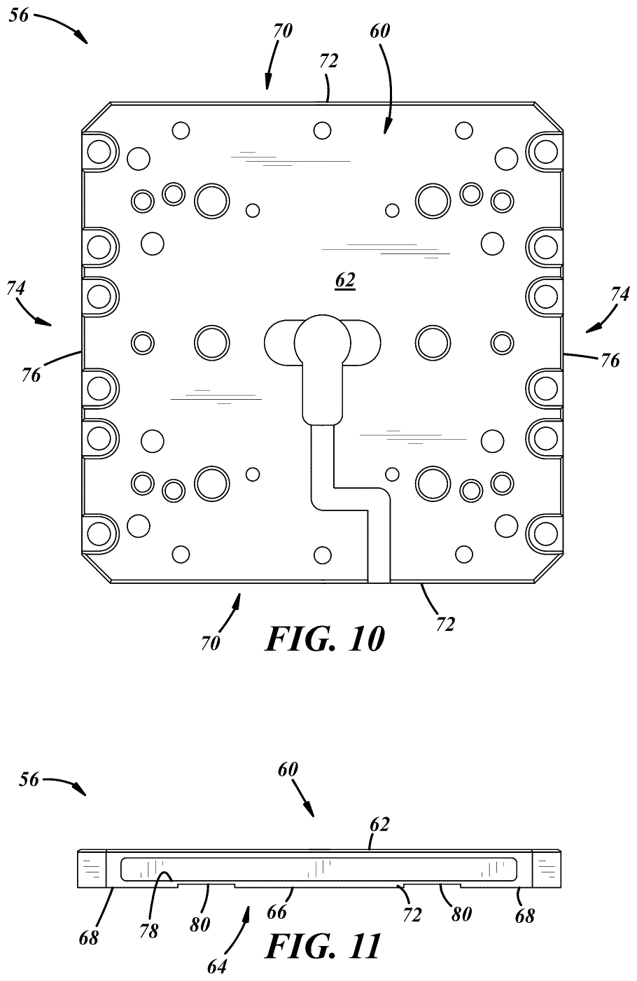

With reference now to FIGS. 10 and 11, the carrier plate 56 may have a carrier top 60 with a top surface 62, and a carrier bottom 64 with a bottom or position receiver mounting surface 66 corresponding to and facing the position driver mounting surface 30 of the top 28 of the base plate 18 of the base 12, and carrier bearing mounting surfaces 68 outboard of the position receiver mounting surface 30. The carrier plate 56 also may have carrier ends 70 with carrier end surfaces 72 extending between the carrier bottom 64 and the carrier top 60, and carrier sides 74 with carrier side surfaces 76 extending between the carrier bottom 64 and the carrier top 60 and between the carrier ends 70. The carrier plate 56 also may include toe clamp pockets 78, for example, in the carrier end surfaces 72 (see FIG. 1) and/or in the carrier side surfaces 76, to receive toe clamps (not shown) during production of the carrier plate 56. The carrier plate 56 also may have base bearing clearance surfaces 80 outboard of the position receiver surface 66.

With reference again to FIGS. 1 and 2, the carrier 14 also may include carrier bearing adjustment flanges 82 at sides 74 of the carrier plate 56, extending toward the base 12, and carrying the carrier bearings 58 at inboard surfaces thereof. The flanges 82 may be composed of titanium, or any other suitable non-ferrous metal. The outboard locations of the carrier bearings 58, in contact with, and/or in close proximity to, the flanges 82, provide a good thermal pathway, for example, that may be coupled to high purity aluminum thermal straps (not shown) or the like, which, in turn, may be coupled directly to a cryogenic base plate (not shown) or indirectly via a cryogenic conductor (not shown). Such straps may be fastened to threaded adjustment holes 84 in the bearing flanges 82 of the carrier 14. If the flanges 82 are no longer desired for such a thermal pathway or other use, then the flanges 82 may be unfastened from the carrier plate 56, thereby leaving sides of the bearings 58 exposed. Also, the carrier plate 56 may be provided with suitable mounting holes 48 that may be threaded and/or with toe clamps (not shown) to facilitate mounting of other equipment to the nanopositioner 10. The carrier plate 56 may be composed of titanium, or any other suitable non-ferrous metal.

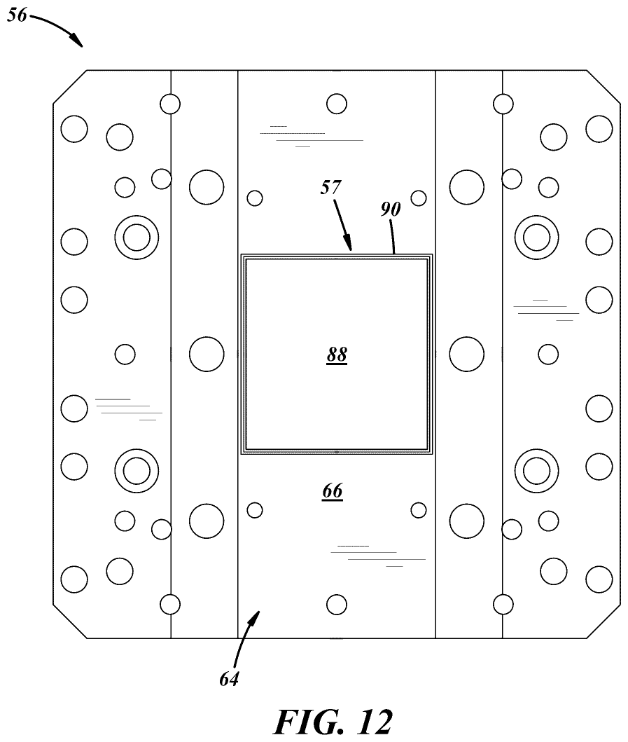

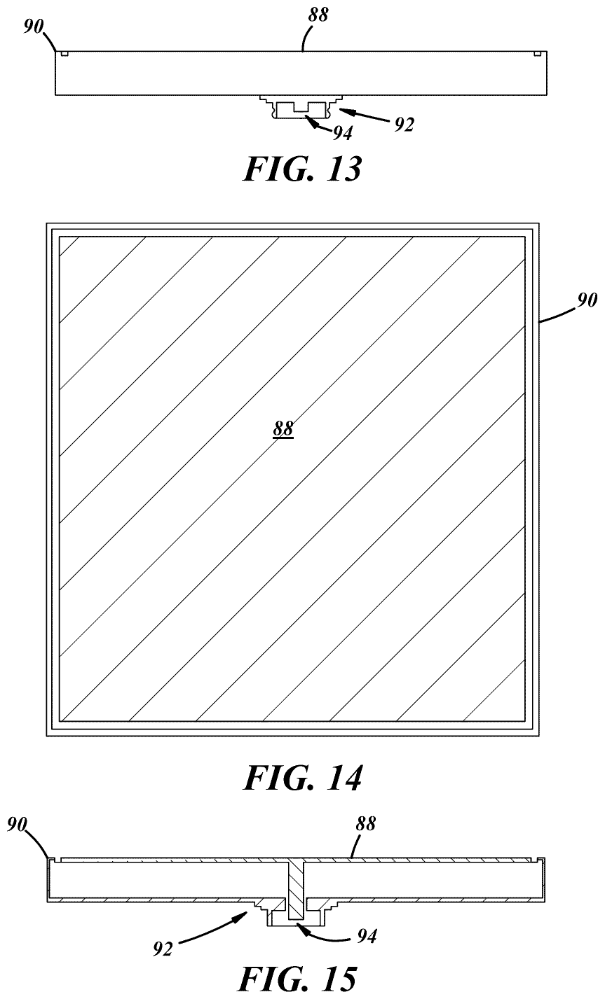

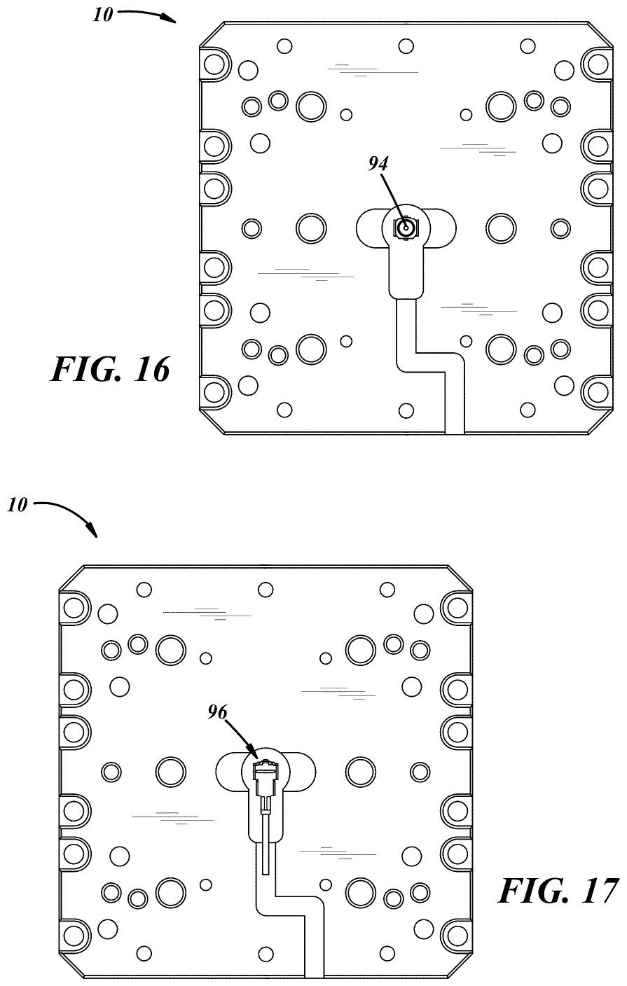

With reference now to FIG. 12, the position receiver 57 may be carried by the position receiver mounting surface 30 of the bottom of the carrier plate 56 and includes a driven or sense electrode 88 operatively coupled to the set of drive electrodes 52a,b (FIG. 9). With reference now to FIGS. 13-15, the position receiver 57 may include a guard electrode 90 having a portion that may surround the sense electrode 88. The guard electrode 90 may have a central coaxial shield 92 and the sense electrode 88 may have a central coaxial conductor 94 extending through the central coaxial shield 92 of the guard electrode 90. The central coaxial conductor 94 can be seen in plan view in FIG. 16, and is shown connected to a sensor cable 96 in FIG. 17.

With reference again to FIG. 2, the sense electrode 88 and the set of drive electrodes 52 may at least partially establish an area variation sensor, or variable area capacitive position sensor. Capacitance is a function of surface area of opposed surfaces divided by distance between the surfaces, wherein conventional capacitive position sensing typically involves measuring variation of the distance between opposed surfaces having fixed areas. With the presently disclosed internal position instrumentation, however, capacitive position sensing involves measuring variation of surface area portions of a drive electrode relative to a fixed surface area of a sense electrode with a fixed distance between the drive and sense electrodes, as will be described further herein below.

With general reference to FIGS. 2, 5, and 12, the sensor includes a differential electrode configuration. With specific reference to FIG. 5, the drive electrode configuration includes a first, female-shaped, electrode 52a and a second, male-shaped electrode 52b spaced from the first electrode 52a. The electrodes 52a,b are coupled to the base 12 and may be driven with high frequency sinewaves, 180 degrees out of phase with each other. With specific reference to FIG. 12, the electrode configuration also includes a third, common or single, sense electrode 88 attached to the carrier 14. The interdigitated configuration of the electrodes 52a,b may render position sensing insensitive or less sensitive to tilt between the sense and drive electrodes 88, 52. Otherwise, for example, tilt of the position drive board 50 relative to the carrier 14 might result in the sense electrode 88 being overly influenced by the drive electrode 52 whose surface area 50 is tilted relatively more with respect to the carrier 14. The nanopositioner 10 could be configured to reverse the electrodes, such that the first and second electrodes could be carried by the carrier 14 and the third electrode could be carried by the base 12.

The overlap area from the first electrode 52a to the third electrode 88, and from the second electrode 52b to the third electrode 88 results in a variable differential capacitor which can then be measured and used to determine the position of the carrier 14 relative to the base 12. When the sense electrode 88 is centered on the first and second drive electrodes 52a,b, the system is balanced such that the sensor reports zero signal. If the sense electrode 88 is offset from the centered position toward the first electrode 52a, it will report a non-zero waveform with the phase of the first electrode 52a corresponding to the area of the offset position.

The internal position instrumentation including the position driver 20 and/or the position receiver 57 may be configured so that there may be a gap between the driver and sense electrodes 52, 88 of between 50 and 100 microns including all ranges, sub-ranges, endpoints, and values in that range. The gap may be held to within plus or minus one micron. For a sensor of this type to have good performance, particular dimensions of the nanopositioner 10 are provided to establish the precise gap between the drive and sense electrodes 52, 88 both initially during manufacturing, and while in use. As will be described below with respect to a method of producing a nanopositioner 10, the gap may be set initially with high precision. Further, the bearings 22, 58 may constrain motion in a manner that results in low variance of the gap across the range of end-to-end motion of the carrier 14 relative to the base 12 and maintain consistency of the gap for good repeatability of position measurements.

With continued reference to FIG. 2, the set of carrier bearings 58 may be carried by the carrier bearing mounting surfaces 84 of the bottom 64 of the carrier plate 56 and is operatively coupled to the set of base bearings 22 of the base 12. The set of carrier bearings 58 may be carried outboard of the position receiver 57, and may include vee groove rails to cooperate with the ball bearings and cage creep stoppers of the set of base bearings 22.

The sets of base and carrier bearings 22, 58 may be linear precision guideways available from PM Linear of the Netherlands. Each bearing rail has a datum plane established by a mounting surface for mounting to a respective one of the base 12 or the carrier 14, and a bearing plane corresponding to and extending through a center or nadir of a vee groove of the bearing rail 62. The bearing manufacturer may hold parallelism between the datum plane and the bearing plane to below two microns.

With reference to FIG. 2, the actuator 16 includes a stator 98 fixed with respect to the base 12, and an armature 100 operatively coupled to the stator 98, extending through the actuator aperture 44 of the base plate 18 of the base 12, and coupled to the carrier 14. As used herein, the term “stator” includes, for example, a drive portion of an actuator 16 that communicates or imposes a motive force but remains relatively fixed, and the term “armature” includes, for example, a driven portion of the actuator 16 that receives or responds to the motive force and moves in response thereto.

The stator 98 of the actuator 16 may be removably coupled to the bottom surface 26 of the base 12 to facilitate removal and replacement of at least a portion of the stator 98. This may be in contrast to typical conventional nanopositioners that typically have stators non-removably fixed to a base. As used herein, the term “non-removably” means that the stator 98 cannot be removed from the base 12 without permanent damage to some portion of the stator 98. For example, many conventional nanopositioners have stators that are epoxied to the base, wherein the epoxy must be melted, cut, or otherwise removed and some mounting portion of the stator in contact with the epoxy must be replaced.

The presently disclosed stator 98 may include a biasing element coupled to the base 12, for instance, a leaf spring 102 fastened to the base 12, for example, the bottom surface 26 of the base 12. The leaf spring 102 may be composed of beryllium copper, other copper alloy, or any other suitable non-ferrous metal. The stator 98 also may include a preload plate 104 positioned between the leaf spring 102 and the armature 100, a ball bearing pivot 106 that may be carried by the leaf spring 102 and in contact with the preload plate 104, a shear piezoelectric stack 108 that may be carried between the preload plate 104 and the armature 100, and a sliding bearing element, for example, a round disk 110, which may be fixed to the shear piezoelectric stack 108 and in slip-stick contact with the armature 100. The preload plate 104 may be composed of MACOR®, or any another suitable ceramic. The ball bearing pivot 106 may include two or any other suitable quantity of ball bearing elements, which may be composed of ceramic, silicon nitride, or the like. The sliding bearing element 110 may be a polished sapphire. Accordingly, in contrast to conventional nanopositioners that typically require disassembly of a carrier 14 from a base 12 to remove and replace a piezo stack 108, the presently disclosed mounting configuration of the stator 98 with respect to the base 12 may facilitate removal and replacement of a piezo stack 108 without having to disassemble the carrier 14 from the base 12. Moreover, some conventional nanopositioner designs do not facilitate removal and replacement of a piezo stack 108 such that the entire nanopositioner 10 must be removed and replaced. The presently disclosed configuration may provide a significant economical improvement over such conventional designs.

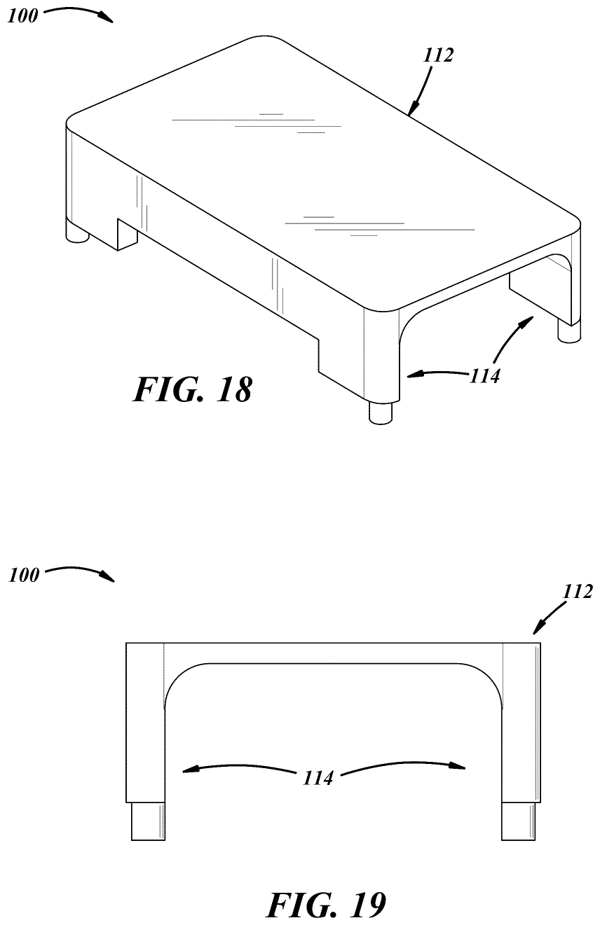

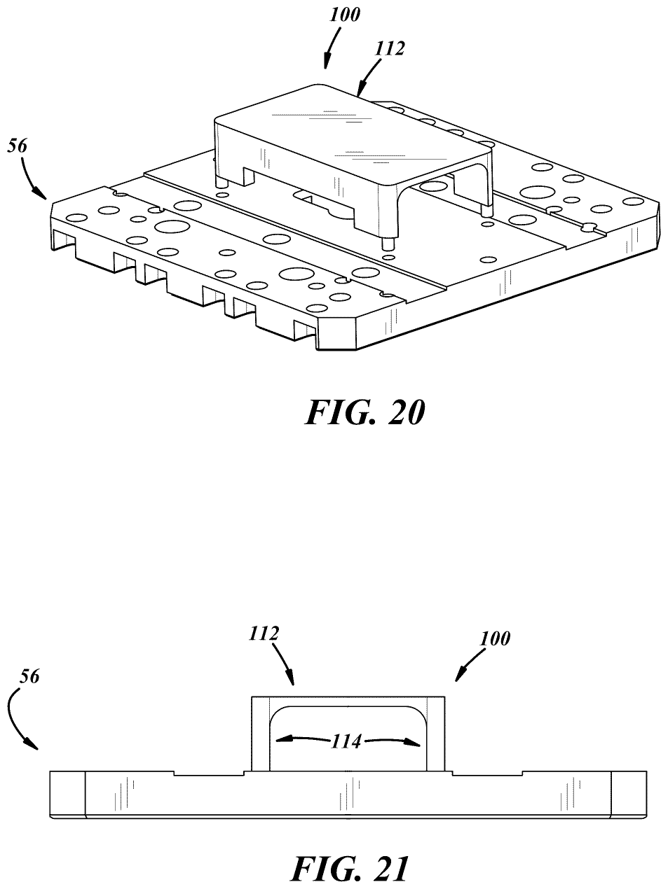

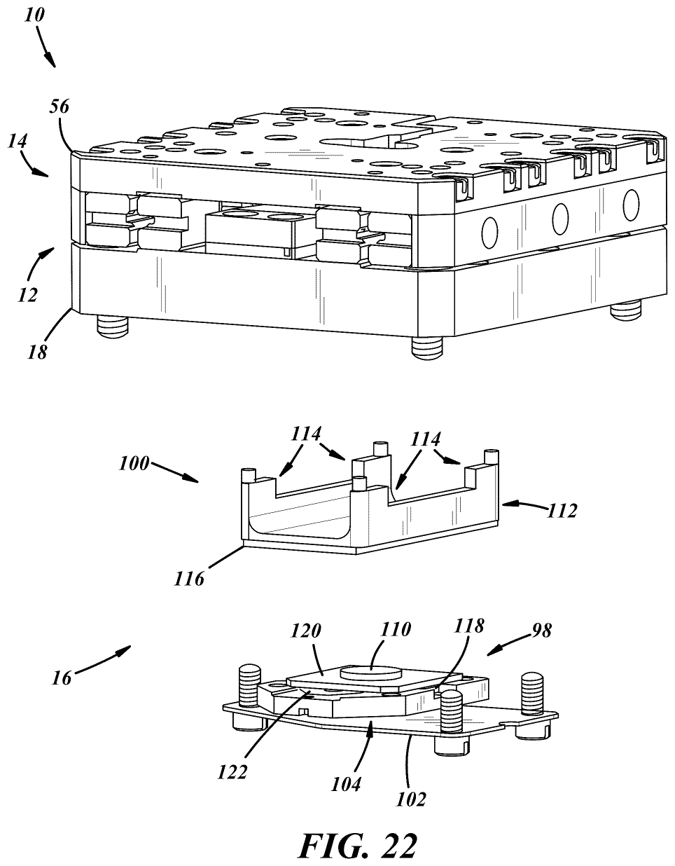

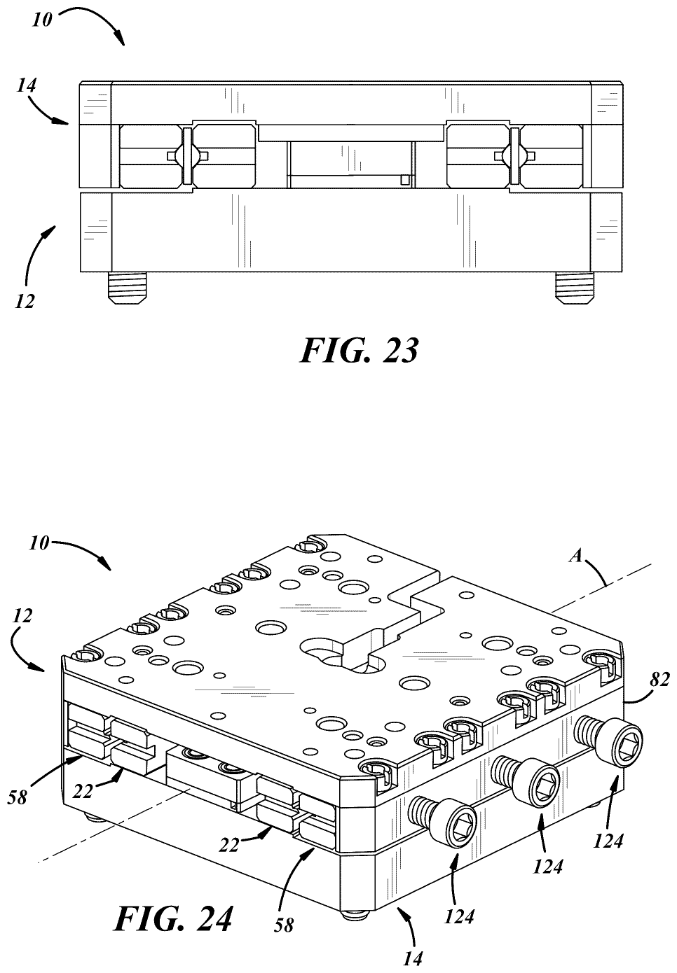

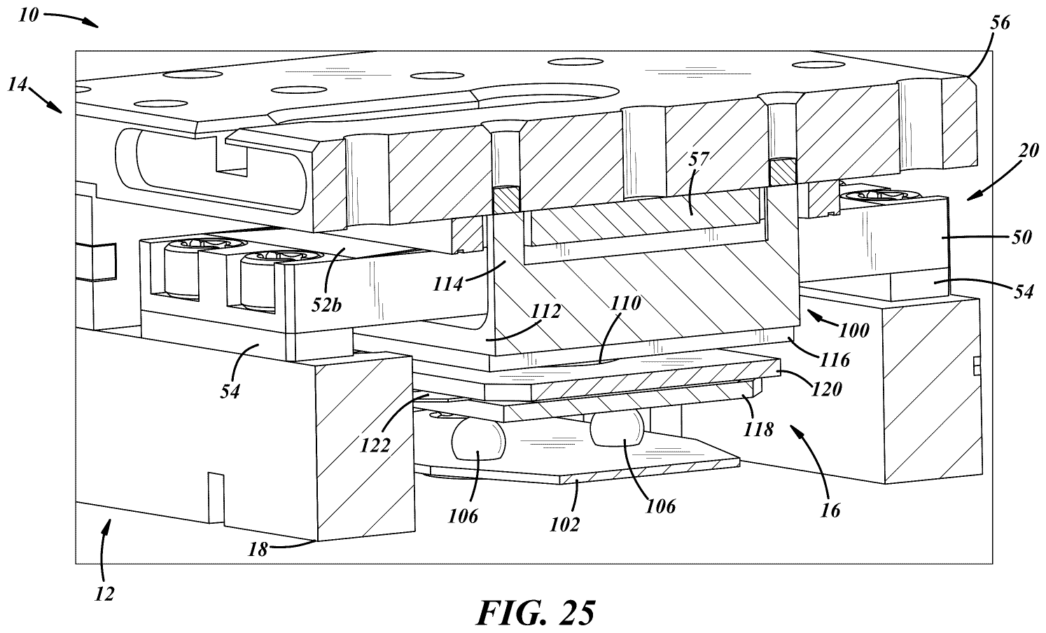

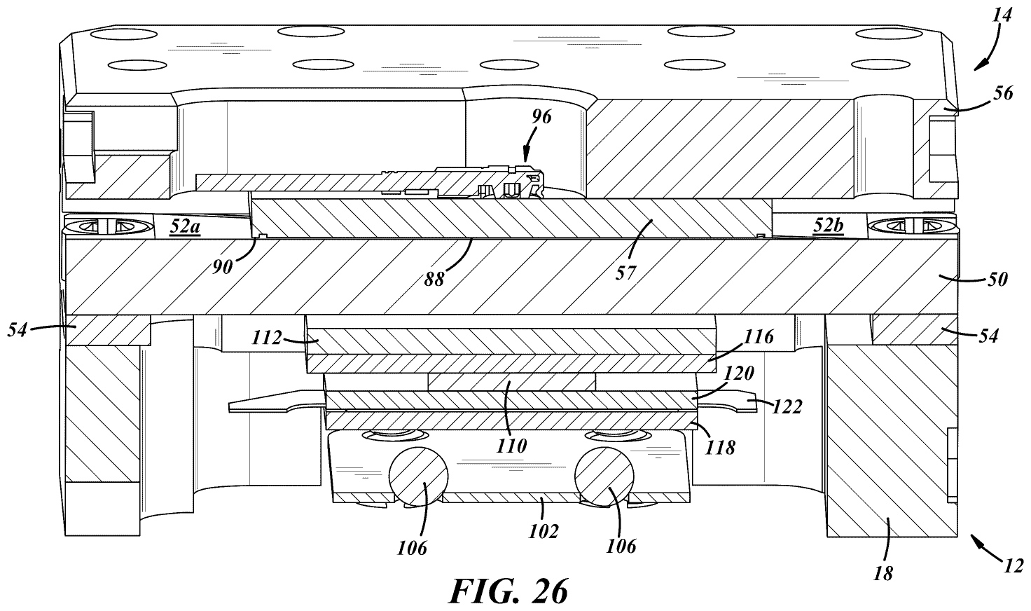

With reference to FIGS. 18-21, the armature 100 of the actuator 16 may be table-shaped. For example, the armature 100 may include a platform 112 and legs 114 extending away from the platform 112 toward the carrier 14 and coupled to the carrier 14, for example, doweled into the carrier plate 56 of the carrier 14. With reference to FIG. 22, the armature 100 may include a sliding bearing element, for example, a sheet 116, which may be carried by the platform 112, for instance, on an external surface of the platform. The sliding bearing element 116 may be a polished sapphire or alumina member that may be of rectangular shape. In another embodiment, the armature 100 may be composed of beryllium copper wherein the external surface of the platform 112 may be polished to a mirror finish, and wherein the armature 100 need not include the sheet carried on the platform 112. Additionally, the external surface of the platform 112 may be plated with gold to further reduce the friction coefficient or may be treated with a lubricant, for example, tungsten disulfide.

With continued reference to FIG. 22, the actuator 16 may include a custom designed and/or constructed actuator, or a commercially available actuator. In a slip-stick piezoelectric actuator embodiment, the actuator 16 preferably exhibits capacitance of less than 2 microfarads and, more specifically, between 5 and 40 nano-farads, including all ranges, sub-ranges, endpoints, and values in that range. A piezo stack 108 may include a base or primary piezoelectric element 118, a secondary piezoelectric element 120 carried on the base piezoelectric element 118, and a conductive foil 122 between the primary and secondary piezoelectric elements 118, 120. The conductive foil 122 may be composed of copper, or gold, silver, bronze, lead, nickel silver, beryllium copper, tungsten, tantalum, or any other material suitable for use as a conductive foil. A conductor (not shown) may be coupled to the copper foil 122 at a positive terminal of the conductor. The sliding bearing element 110 may be epoxied to the secondary piezoelectric element 120. The piezoelectric elements may be composed of PZT (lead zirconate titanate) or, lithium niobate (LiNbO₃), or any other suitable piezoelectric material(s). The piezoelectric elements may be CSAP03 noliac shear plate actuators, with a max operating voltage of +/−320 V and corresponding free stroke of 1.5 microns and a capacitance of 3.32 nF, obtainable from CTS Ceramics of Denmark, and similar products may be obtainable from Physik Instrumente or any other suitable supplier. A particular piezoelectric actuator will be described in further detail herein below, with reference to a method of producing a piezoelectric actuator.

In operation, the nanopositioner 10 is controlled in any suitable manner, for example, to apply power to the actuator 16 and to the internal position instrumentation, and to process position sensor signals. Those of ordinary skill in the art would recognize that control of the nanopositioner 10 may be facilitated by one or more processors, memory coupled to the processor(s), and any suitable instructions carried out by the processor(s) and data stored in the memory. Such facilitating subject matter is not the subject of the present disclosure and any suitable such subject matter may be used.

In the slip-stick piezoelectric actuator embodiment, the piezo stack 108 may be powered so as to relatively rapidly push the sliding bearing element 110 across the sliding bearing sheet 116 and so as to relatively slowly pull the sliding bearing sheet 116 via fixed frictional contact with the disk 110, in a cyclical manner to achieve desired displacement of the carrier 14 relative to the base 12. For example, in a slip-stick piezoelectric actuator embodiment, an actuator power supply (not shown) may include a DC power supply or any other power supply suitable to provide voltage levels compatible with piezoelectric limits, and a waveform generator connectable to the power supply and that may produce periodic signals, for instance, sawtooth-shaped waveforms, sigmoid-shaped waveforms, exponential waveforms, and any other waveforms of any other shape(s) suitable for use in driving a piezoelectric motor. The power supply may provide output power including between 10 and 2,000 volts including all ranges, sub-ranges, endpoints, and values in that range, and including between 0.001 and 0.5 amps including all ranges, sub-ranges, endpoints, and values in that range. In a more specific example, the power supply may provide between 50 and 600 volts, including all ranges, sub-ranges, endpoints, and values in that range, and between 0.1 and 0.3 amps, including all ranges, sub-ranges, endpoints, and values in that range. Those of ordinary skill in the art would recognize that the parameter values of the motor drive 16 differ between ambient temperatures (e.g., 65 to 80 degrees Fahrenheit) and cryogenic temperatures. For example, at ambient temperatures, the motor drive may operate between 100 Hz and 2 kHz, including all ranges, sub-ranges, endpoints, and values in that range, and provide between 30 and 200 volts, including all ranges, sub-ranges, endpoints, and values in that range, and between 0.1 and 0.3 amps, including all ranges, sub-ranges, endpoints, and values in that range. In contrast, at cryogenic temperatures, the same motor drive may operate between 100 and 4 kHz, including all ranges, sub-ranges, endpoints, and values in that range, and provide between 200 and 300 volts, including all ranges, sub-ranges, endpoints, and values in that range, and between 0.1 and 0.3 amps, including all ranges, sub-ranges, endpoints, and values in that range.

Likewise, the internal position instrumentation may be powered in any manner suitable for use with a nanopositioner, particularly a cryogenic nanopositioner. For example, high precision low voltage may be transmitted to the instrumentation in any suitable manner. And signals from the instrumentation may be received through a preamplifier and sent to a processor, for instance, and FPGA where they may be demodulated and correlated with a functional fit to output position in user specified units of length.

As a result, the nanopositioner 10 is capable of performing with positional repeatability on the order of 200 nanometers (e.g., 100-300 nanometers). Therefore, the performance of the nanopositioner 10 may be three orders of magnitude better than that available from presently available internally instrumented nanopositioners. Thus, the presently disclosed nanopositioner 10 may represent a new standard of performance in the industry.

In accordance with the various embodiments described above and illustrated in the drawing figures, an illustrative method of producing a nanopositioner 10 involves several steps. The method may or may not include all of the disclosed steps or be sequentially processed or processed in the particular sequence discussed, and the presently disclosed method may encompass any sequencing, overlap, or parallel processing of such steps.

The method may include processing top and bottom surfaces of a nanopositioner base plate 18 to be parallel to each other within a base plate tolerance, for example, between 0 and 2 microns, including all ranges, sub-ranges, endpoints, and values in that range, but preferably below 1 micron. For example, the processing step may include surface grinding the top and bottom surfaces, or lapping, high-precision milling, or any other suitable material removal process. In a surface grinding example, a feedrate or stepover may be about 2 mm, and the base plate may be clamped to a steel plate carried on a magnetic plate, by using toe clamps (not shown) fastened to the steel plate and clamped to the toe clamp pockets 42 of the base plate 18.

The method may include processing top and bottom surfaces 82 of a nanopositioner carrier plate 56 to be parallel to each other within a carrier plate 56 tolerance, for example, between 0 and 2 microns, including all ranges, sub-ranges, endpoints, and values in that range, but preferably below 1 micron. For example, the processing step may include surface grinding the top and bottom surfaces, or lapping, high-precision milling, or any other suitable material removal process. In a surface grinding example, a feedrate or stepover may be about 2 mm, and the carrier plate may be clamped to a steel plate carried on a magnetic plate, by using toe clamps (not shown) fastened to the steel plate and clamped to the toe clamp pockets 42 of the carrier plate 56.

The method may include mounting an actuator armature 100 to the bottom surface 82 of the carrier plate 56. For example, the carrier plate 56 may be positioned upside down and the legs of the actuator armature 100 may be inserted into corresponding dowel holes in the carrier plate 56.

The method may include processing a bottom surface of the platform 112 of the armature 100 to be parallel to the top surface 62 of the carrier plate 56 within an armature 100 tolerance, for example, between 0 and 2 microns, including all ranges, sub-ranges, endpoints, and values in that range, but preferably below 1 micron. For example, the processing step may include surface grinding the bottom surface of the platform 112, or lapping, high-precision milling, or any other suitable material removal process. In a surface grinding example, a feedrate or stepover may be about 2 mm on the slow axis; while a fast axis feedrate may be 100-500 mm/s.

The method may include removing the actuator armature 100 from the carrier plate 56, after the armature surface grinding step. For example, the legs 114 of the actuator armature 100 may be removed from the corresponding dowel holes in the carrier plate 56, for instance, by simply lifting the armature 100 away from the carrier plate 56.

The method may include mounting a position receiver 57 to the bottom surface 82 of the carrier plate 56. For example, the position receiver 57 shown in FIG. 12 can be applied to the bottom surface 82 of the carrier plate 56, for instance, using an epoxy, or adhering the position receiver 57 to the carrier plate 56 with any other suitable adhesives, or by coupling the position receiver 57 to the carrier plate 56 with fasteners or in any other suitable manner.

The method may include mounting position drive board standoffs 54 to the top surface of the base plate 18. For example, the drive board standoffs 54 may be of identical thickness, initially, and may be coupled to the top surface of the base plate 18, for example, using an epoxy or any other suitable adhesive, or using fasteners, or in any other suitable manner.

The method may include mounting a position drive board 50 onto the standoffs 54 on the top surface of the base plate 18. For example, the position drive board 50 may be coupled to the standoffs 54, for example, using an epoxy or any other suitable adhesive, or using fasteners, or in any other suitable manner.

The method may include measuring parallelism of the position drive board 50 to obtain parallelism measurements of the drive board 50, for example, at opposite ends of the drive board 50. For example, the parallelism may be measured using an interferometer.

The method may include processing top surfaces of the drive board standoffs 54 using the parallelism measurements so that a top surface of the drive board 50 is parallel to the bottom surface 26 of the base plate 18 within a drive board tolerance, for example, between 0 and 2 microns, including all ranges, sub-ranges, endpoints, and values in that range, but preferably below 1 micron. For example, the processing step may include surface grinding the top surfaces of the standoffs 54, or lapping, high-precision milling, or any other suitable material removal process. Of course, the top surfaces of the standoffs 54 may be processed differently or to a different degree depending on how far out of parallel the standoffs 54 are from one another initially.

The method may include mounting sets of bearings 22 to the top surface 162 of the base plate 18 and to the bottom surface 82 of the carrier plate 56. The sets of bearings 22 may include sets of linear bearings. The sets of bearings 22 may be fastened respectively to the base and carrier plates 18, 56, for instance, via fasteners extending through the plates 18, 56 and into the sets of bearings 22, 58. The base bearing rails may be spaced apart from one another to specification using one or more gage blocks and then are fastened to the base 12. The carrier bearing rails may be spaced apart from one another slightly more than specification, for example, between 100 and 400 microns more including all ranges, sub-ranges, endpoints, and values in that range, and then are fastened to the carrier 14. Although the base bearings 22 may be completely tightly fastened to the base 12, the carrier bearings 58 may be loosely fastened to the carrier plate 56 to permit adjustment thereto as discussed below.

The method may include assembling the carrier 14 to the base 12. The carrier 14 is located to the base 12 so that the bearing rails are opposed from one another, and then bearing cages are initially inserted between the bearing rails and each bearing ball 64 is assembled between the bearing rails and the bearing cages are advanced between the bearing rails and this is done one ball at a time until all balls have been assembled.

The method may include setting the sets of bearings 22, for example, into proper engagement with one another. For example, with reference to FIG. 24, the sets of carrier bearings 58 may be moved laterally toward a central longitudinal axis A of the nanopositioner 10 into suitable engagement with the sets of base bearings 22. For instance, adjustment screws 124 may be inserted through corresponding threaded adjustment holes 84 in the bearing flanges 82 of the carrier 14 and threaded into abutting engagement with the sets of carrier bearings 58 to move the carrier bearings 58 and ensure that bearing balls and vee grooves make appropriate contact. The adjustment screws may be threaded simultaneously to set the bearings 58 and thereafter may be removed. Thereafter, the carrier bearings 58 are completely tightly fastened to the carrier plate 56. To facilitate some play of the carrier bearings 58 relative to the carrier plate 56, carrier bearing fastener holes in the carrier plate 56 may be slightly oversized, but it is contemplated that typical fastener to fastener hole tolerances will facilitate the 10 to 100 micron or so adjustment of the carrier bearings 58.

The method may include mounting the actuator armature 100 to the carrier plate 56. For example, a portion of the actuator armature 100 may be inserted through the actuator armature aperture 44 in the base plate 18. For instance, the legs of the actuator armature may extend through the aperture 44 and be inserted into corresponding holes in the bottom surface 82 of the carrier plate 56, such that the actuator armature 100 straddles the position drive board 50 with clearance therebetween and so as to not contact the sense electrode 88. Therefore, the actuator armature 100 straddles the position driver 20 and the position receiver 57 of the internal position instrumentation, such that the actuator 16 and the internal position instrumentation are mechanically decoupled with respect to one another. Thus, the internal position instrumentation can be installed, and then the actuator 16 can be installed separately, thereby facilitating removal and replacement of the actuator 16.

The method may include coupling a sliding bearing element 110 to the platform 112 of the actuator armature 100. For example, the sliding bearing element may be the sheet 116 that may be epoxied or otherwise adhered, or otherwise coupled, to the platform 112 in any suitable manner. Preferably, this step is carried out after the actuator armature 100 is assembled to the carrier 14.

The method may include mounting an actuator stator 98 to the base plate 18 to trap the actuator armature 100 between the actuator stator 98 and the carrier plate 56. For example, the leaf spring 102 of the actuator stator 98 may be fastened to the bottom surface 26 of the base plate 18 so that the disk 110 of the stator 98 is in contact with the sheet 116 of the actuator armature 100. The piezoelectric actuator shown in FIG. 22 may be produced by a method of producing a piezoelectric actuator in accordance with the present disclosure and as follows.

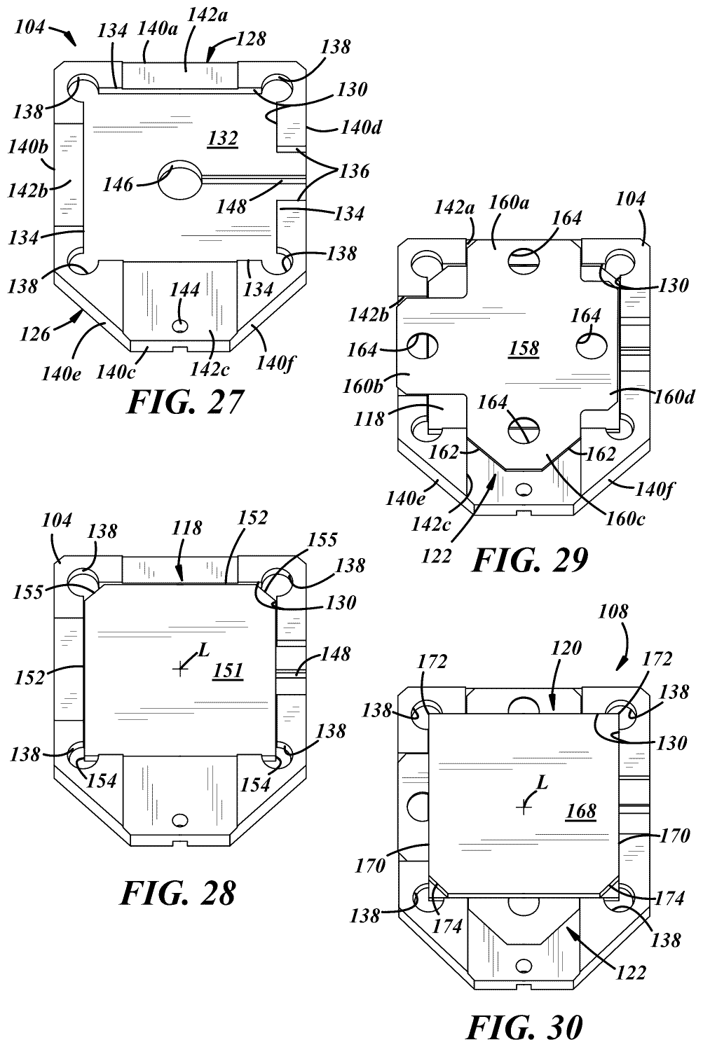

With reference now to FIG. 27, the preload plate 104 (or “piezo stack carrier”) includes a base 126 or mounting face and an oppositely disposed piezo face 128. The preload plate 104 also may include a piezo pocket 130 in the piezo face 128 to carry the piezo stack 108 and having a piezo support surface 132 at a bottom of the pocket 130 on which the piezo stack 108 is supported. The piezo pocket 130 may be established by surrounding walls 134 extending away from the piezo support surface 132 and that may include at least three complete walls and at least a fourth wall that may have a lateral slot 136 extending laterally therethrough. The pocket 130 may be rectangular, for example, square, as illustrated, and may include semi-circular cutouts 138 at corners of the piezo pocket 130. The preload plate 104 may have any suitable quantity of sides 140a-f, for example, four sides, five sides, or, as illustrated, may have six sides. Fifth and sixth sides may be beveled and may connect the second and third sides and the third and fourth sides.

Additionally, the preload plate 104 may include one or more foil tab slots 142a-c in communication with the piezo pocket 130 and extending through one or more sides 140a-f of the preload plate 104. In the illustrated embodiment, a first foil tab slot 142a may extend orthogonally through a first side 140a (e.g., at a twelve o'clock position), a second foil tab slot 142b may extend orthogonally through a second side 140b (e.g., at a nine o'clock position), and a third foil tab slot 142c may extend orthogonally through a third side 140c (e.g., at a six o'clock position). The preload plate 104 also may include a foil pocket, which, in addition to a portion of the piezo pocket 130, also may include one or more of the foil tab slots 142a-c through at least one of the surrounding walls 134. The preload plate 104 may include a through hole 144 proximate the third side 140c to facilitate routing a negative lead or wire (not shown) therethrough.

With continued reference to FIG. 27, the preload plate 104 further may include lead or wire routing features. For example, the preload plate 104 may include a central through hole 146 extending through the preload plate 104 in a central location of the pocket 130, between the base 126 and piezo sides 140a-f and in communication with the base 126 and piezo support surfaces 132. The preload plate 104 also may include a channel 148 in the piezo support surface 132 and in communication with the through hole 144 and extending from the through hole 144, through the lateral slot 136, to a fourth side 140d of the preload plate 104. The preload plate 104 may be configured to carry a piezo stack 108 that may be retained by the surrounding walls 134 of the preload plate 104, as discussed below.

With reference now to FIG. 28, a base or primary piezoelectric element 118 is assembled to and carried in the piezo pocket 130 of the preload plate 104. The term “piezo” is used herein interchangeably with “piezoelectric element” for simplicity. The primary piezo 118 has primary opposite faces 151 through which a normal axis L of the piezo stack 108 extends, and primary sides 152 extending between the primary opposite faces 151 and establishing a laterally outer perimeter that has a geometry that may match the perimetric geometry of the pocket 130. For example, the primary piezo 118 may be rectangular and, more specifically, may be square or square-shaped. For instance, the primary piezo 118 may have primary vertices 154 extending between the primary opposite faces 151 and establishing primary corners between the primary sides 152 that may overlap corresponding semi-circular cutouts 138 of the preload plate 104, and primary bevels 155 (two shown on same side) extending between the primary opposite faces 151 and being oriented in a first orientation. The primary piezo 118 may cover the through hole 144 of the preload plate 104 and at least part of the lateral slot 136. The primary piezo 118 may be a shear piezo that may be coupled to the preload plate 104 via epoxy or any other suitable adhesive or coupled in any other suitable manner. In this position, a wire (not shown) can be inserted through the lateral slot 136 to the through hole 144 and then coupled to the piezo 118, for example, via soldering, spot welding, or in any other suitable manner.

With reference now to FIG. 29, an electrically conductive foil 122 is assembled to and carried on the primary piezo 118 within the piezo pocket 130 of the preload plate 104. As used herein the term foil includes any foil-like or plate-like component that has a thickness that is less than thicknesses of each of the primary and secondary piezos 118, 120. The foil 122 may include a central body 158 covering a central portion of the primary piezo 118, and at least one tab extending laterally away from the central body 158. In the illustrated embodiment, the foil 122 includes a first tab 160a that may extend orthogonally away from the central body 158 and that may be carried within the first foil tab slot 142a of the preload plate 104, a second tab 160b that may extend orthogonally away from the central body 158 and that may be carried within the second foil tab slot 142b of the preload plate 104, and a third tab 160c that may extend orthogonally away from the central body 158 and that may be carried within the third foil tab slot 142c of the preload plate 104. The third tab 160c may be beveled as an orientation feature to help an assembler correctly orient the foil 122 relative to the preload plate 104. For instance, the foil bevels 162 may correspond to the preload plate bevels 155 or beveled sides to assist with orientation of the conductive foil 122 with respect to the preload plate 104. The foil 122 also may include a fourth tab 160d that may be wider than one or more of the other tabs. One or more of the tabs may include apertures 46 that may facilitate handling with tweezers, or any other suitable tool(s). The foil 122 may be coupled to the primary piezo 118, for example, via a conductive epoxy or any other suitable adhesive, or coupled in any other suitable manner. One or more of the tabs 160a-c may rest on one or more corresponding surfaces of the plate 104 that establish the corresponding tab slots 142a-c.

With reference now to FIG. 30, a second or secondary piezo 120 is assembled to and carried on the foil 122 and at least partially in the piezo pocket 130. The secondary piezo 120 has secondary opposite faces 168 through which a longitudinal axis L of the piezo stack 108 extends, and secondary sides 170 extending between the secondary opposite faces 168 and establishing a laterally outer perimeter that has a geometry that may match the perimetric geometry of the pocket 130. For example, the secondary piezo 120 may be rectangular and, more specifically, may be square or square-shaped. For instance, the secondary piezo 120 may have secondary vertices 172 extending between the secondary opposite faces 168 and establishing secondary corners between the secondary sides 170 that may overlap corresponding semi-circular cutouts 138 of the preload plate 104, and secondary bevels 174 (two shown on same side) extending between the secondary opposite faces 168 and being oriented in a second orientation opposite that of the first orientation of the primary piezo 118. The oppositely oriented bevels indicate proper polarity of the piezo elements relative to one another. The secondary piezo 120 may be coupled to the foil 122, for example, via a conductive epoxy or any other suitable adhesive, or coupled in any other suitable manner.

Accordingly, the foil 122 is disposed between facing instances of the primary 151 and secondary 168 opposite faces of the primary and secondary piezoelectric elements 118, 120. One or more of the tabs of the foil 122 may extend laterally outwardly past perimetric edges of the piezoelectric elements 118, 120 to establish lead or wire connection points that are outboard of the piezos to reduce a line-of-sight, and concomitant potential for arcing, between positive and negative electrodes. Preferably, the first tab 160a, second tab 160b, and third tab 160c extend outward of the piezos 118, 120 between 0.5 mm and 2 mm including all ranges, subranges, values, and endpoints of that range. In other words, at least one of the tabs extends outward of the piezos 118, 120 according to a distance that is equal to or greater than the thickness of each piezo. The piezo stack 108 may include only the primary and secondary piezos 118, 120 and foil 122, or may include one or more additional repeating sets of primary and secondary piezos 118, 120 and foil 122 on top of a first set of same.

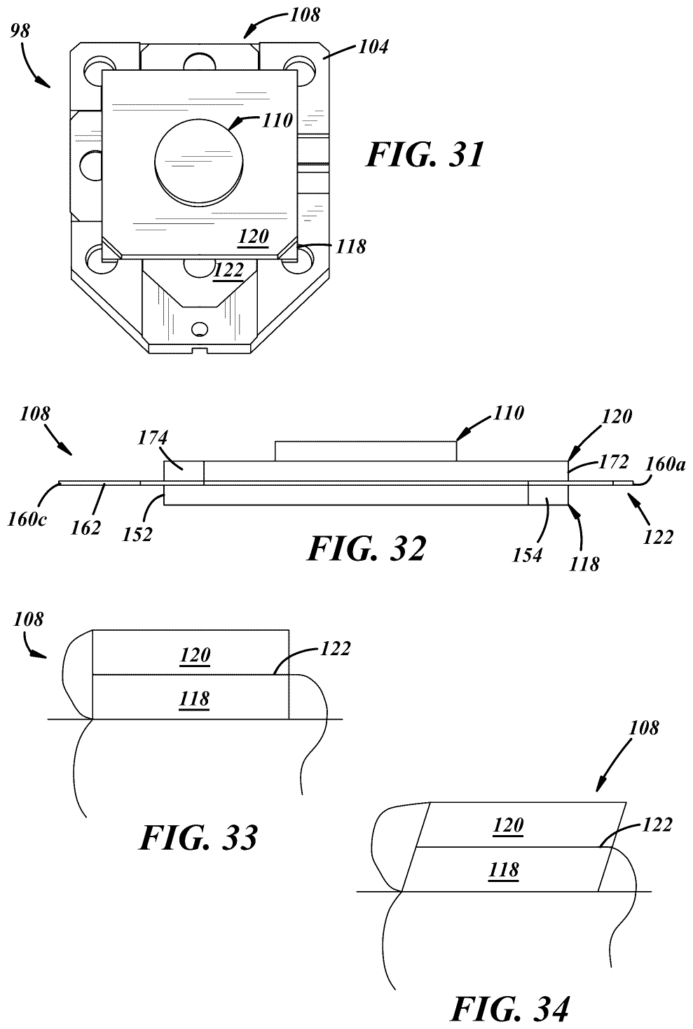

With reference now to FIG. 31, a sliding bearing element 110 is assembled to and carried on the secondary piezo 120. The sliding bearing element 110 may be centrally located on the secondary piezo 120, and may be coupled thereto via epoxy, or any other suitable adhesive, or coupled in any other manner suitable for use with nanopositioners, particularly in cryogenic environments.

A bottom surface of the primary piezo 118 may be conductively coupled to a top surface 168 of the secondary piezo 120. For example, although not shown, a wire may be coupled to the top surface 168 of the secondary piezo 120 anywhere outboard of the sliding bearing element 110 and coupled to the bottom surface of the primary piezo 118, for example, through a through hole 144 of the preload plate 104. The wire may be soldered, spot welded, or coupled to the piezos in any other suitable manner. Also, any of the foil tabs may serve as a positive electrode to which a positive lead or wire (not shown) may be coupled, for example, via soldering, spot welding, or in any other suitable manner. Likewise, although not shown, a negative lead or wire may be coupled to the upper surface of the secondary electrode outboard of the sliding bearing element 110, for example, via soldering, or spot welding, or in any other suitable manner.

With reference now to FIG. 32, a piezo stack 108 is shown, schematically, without the preload plate 104 and including the primary and secondary piezos 118, 120 with the foil 122 sandwiched therebetween and the sliding bearing element 110 carried thereon. The opposite facing configuration of the bevels of the piezos is illustrated. Also, the foil 122 is shown extending well beyond the side perimeters of the piezos.

With reference now to FIGS. 33 and 34, a further simplified piezo stack 114 is shown schematically. In FIG. 33, a negative lead is coupled to oppositely facing sides of the primary and secondary piezos 118, 120, and a positive lead is coupled to commonly facing sides of the primary and secondary piezos 118, 120 (for example, via a common connection to the foil), and the piezos are shown in a state of rest with no voltage applied. In FIG. 33, the piezos are shown in an activated state with a voltage applied.

As used in herein, the terminology “for example,” “e.g.,” “for instance,” “like,” “such as,” “comprising,” “having,” “including,” and the like, when used with a listing of one or more elements, is to be construed as open-ended, meaning that the listing does not exclude additional elements. Also, as used herein, the term “may” is an expedient merely to indicate optionality, for instance, of a disclosed embodiment, element, feature, or the like, and should not be construed as rendering indefinite any disclosure herein. Moreover, directional words such as front, rear, top, bottom, upper, lower, radial, circumferential, axial, lateral, longitudinal, vertical, horizontal, transverse, and/or the like are employed by way of example and not necessarily limitation.

Finally, the subject matter of this application is presently disclosed in conjunction with several explicit illustrative embodiments and modifications to those embodiments, using various terms. All terms used herein are intended to be merely descriptive, rather than necessarily limiting, and are to be interpreted and construed in accordance with their ordinary and customary meaning in the art, unless used in a context that requires a different interpretation. And for the sake of expedience, each explicit illustrative embodiment and modification is hereby incorporated by reference into one or more of the other explicit illustrative embodiments and modifications. As such, many other embodiments, modifications, and equivalents thereto, either exist now or are yet to be discovered and, thus, it is neither intended nor possible to presently describe all such subject matter, which will readily be suggested to persons of ordinary skill in the art in view of the present disclosure. Rather, the present disclosure is intended to embrace all such embodiments and modifications of the subject matter of this application, and equivalents thereto, as fall within the broad scope of the accompanying claims.

1. A nanopositioner, comprising:
a base including
a base plate having
a base bottom with
a bottom surface, and
a base top with
a position driver mounting surface, and
base bearing mounting surfaces outboard of the position driver mounting surface, and
an actuator aperture extending between the bottom surface and the position driver mounting surface,
a position driver carried by the position driver mounting surface of the base top of the base plate and including set of drive electrodes, and
a set of base bearings carried by the base bearing mounting surfaces of the base top of the base plate;
a carrier movably carried with respect to the base and including
a carrier plate having
a carrier top with
a top surface, and
a carrier bottom with
a position receiver mounting surface corresponding to and facing the position driver mounting surface of the base top of the base plate of the base, and
carrier bearing mounting surfaces outboard of the position receiver mounting surface,
a position receiver carried by the position receiver mounting surface of the bottom of the carrier plate and including a sense electrode operatively coupled to the set of drive electrodes, and
a set of carrier bearings carried by the carrier bearing mounting surfaces of the bottom of the carrier plate and operatively coupled to the set of base bearings; and
an actuator operatively coupling the carrier to the base and including
a stator removably coupled to the base to facilitate removal and replacement of at least a portion of the stator, and
an armature operatively coupled to the stator, extending through the actuator aperture of the base plate of the base, and coupled to the carrier,
wherein the sense electrode and the set of drive electrodes at least partially establish a variable area capacitive position sensor.

2. The nanopositioner of claim 1, wherein
the base plate also has carrier bearing clearance surfaces outboard of the position driver mounting surface,
the base bearing mounting surfaces of the base top of the base plate of the base are coplanar with the position driver mounting surface,
the set of base bearings is carried outboard of the set of drive electrodes,
the carrier plate also has base bearing clearance surfaces outboard of the position receiver mounting surface, and
the set of carrier bearings is carried outboard of the position receiver.

3. The nanopositioner of claim 1, wherein
the base plate also has base ends with base end surfaces extending between the base bottom and the base top, and base sides with base side surfaces extending between the base bottom and the base top and between the base ends, and
the carrier plate also has carrier ends with carrier end surfaces extending between the carrier bottom and the carrier top, and carrier sides with carrier side surfaces extending between the carrier bottom and the carrier top and between the carrier ends.

4. The nanopositioner of claim 1, wherein the position driver includes a position drive board bridging over the actuator aperture of the base plate of the base.

5. The nanopositioner of claim 4, further comprising position driver standoffs carrying the position drive board and coupled directly to the position driver mounting surface.

6. The nanopositioner of claim 1, wherein the set of base bearings includes vee groove rails, ball bearings carried between the vee groove rails, ball retention cages to retain the ball bearings to the vee groove rails, and cage creep stoppers, and wherein the set of carrier bearings includes vee groove rails to cooperate with the ball bearings and cage creep stoppers.

7. The nanopositioner of claim 1, wherein the carrier also includes carrier bearing adjustment flanges at sides of the carrier plate, extending toward the base, and adjacent to the carrier bearings at inboard surfaces thereof.

8. The nanopositioner of claim 1, wherein the position receiver also includes a guard electrode having a portion surrounding the sense electrode.

9. The nanopositioner of claim 8, wherein the guard electrode has a central coaxial shield and the sense electrode has a central coaxial conductor extending through the central coaxial shield.

10. A nanopositioner, comprising:
a base including
a base plate including an actuator aperture therethrough,
a position driver carried by the base plate and including a set of drive electrodes, and
a set of base bearings carried by the base plate;
a carrier movably carried with respect to the base and including
a carrier plate,
a position receiver carried by the carrier plate and including a sense electrode operatively coupled to the set of drive electrodes, and
a set of carrier bearings carried by the carrier plate and operatively coupled to the set of base bearings; and
an actuator operatively coupling the carrier to the base and including
an armature fixed with respect to the carrier; and
a stator removably coupled to the base to facilitate removal and replacement of at least a portion of the stator.

11. The nanopositioner of claim 10, wherein the stator of the actuator includes
a leaf spring fastened to the base,
a preload plate positioned between the leaf spring and the armature,
a ball bearing pivot carried by the leaf spring and in contact with the preload plate,
a shear piezoelectric stack carried between the preload plate and the armature, and
a sliding bearing disk fixed to the shear piezoelectric stack and in slip-stick contact with the armature.

12. A nanopositioner, comprising:
a base including
a base plate including an actuator aperture therethrough,
a position driver carried by the base plate and including a set of drive electrodes, and
a set of base bearings carried by the base plate;
a carrier movably carried with respect to the base and including
a carrier plate,
a position receiver carried by the carrier plate and including a sense electrode operatively coupled to the set of drive electrodes, and
a set of carrier bearings carried by the carrier plate and operatively coupled to the set of base bearings;
an actuator operatively coupling the carrier to the base and including
a stator fixed with respect to the base; and
an armature operatively coupled to the stator, extending through the actuator aperture of the base plate of the base, and coupled to the carrier.

13. The nanopositioner of claim 12, wherein the armature of the actuator is table-shaped including a platform and legs extending away from the platform toward the carrier and coupled to the carrier.

14. The nanopositioner of claim 13, wherein the legs are doweled into the carrier.

15. The nanopositioner of claim 13, wherein the platform carries a sliding bearing sheet.

16. A nanopositioner, comprising:
a base including
a base plate including an actuator aperture therethrough,
a position driver carried by the base plate and including a set of drive electrodes, and
a set of base bearings carried by the base plate;
a carrier movably carried with respect to the base and including
a carrier plate,
a position receiver carried by the carrier plate and including a sense electrode operatively coupled to the set of drive electrodes, and
a set of carrier bearings carried by the carrier plate and operatively coupled to the set of base bearings,
wherein the sense electrode and the set of drive electrodes at least partially establish a variable area capacitive position sensor.

17. The nanopositioner of claim 16, wherein the set of drive electrodes include corresponding triangular elements.

18. The nanopositioner of claim 17, wherein the corresponding triangular elements are interdigitated triangular elements.

19. The nanopositioner of claim 18, wherein the interdigitated triangular elements include a guidon-shaped element establishing a triangular space and a triangular-shaped element in the triangular space established by the guidon-shaped element.

20. A method of producing a nanopositioner, comprising:
processing top and bottom surfaces of a base plate to be parallel to each other within a base plate tolerance;
processing top and bottom surfaces of a carrier plate to be parallel to each other within a carrier plate tolerance;
mounting an actuator armature to the bottom surface of the carrier plate;
processing a bottom surface of a platform of the actuator armature to be parallel to the top surface of the carrier plate within an armature tolerance;
removing the actuator armature from the carrier plate;
mounting a position receiver to the bottom surface of the carrier plate;
mounting position drive board standoffs to the top surface of the base plate;
mounting a position drive board onto the standoffs on the top surface of the base plate;
measuring parallelism of the position drive board to obtain parallelism measurements of the drive board; and
processing top surfaces of the drive board standoffs using the parallelism measurements so that a top surface of the drive board is parallel to the bottom surface of the base plate within a drive board tolerance.

21. The method of claim 20, wherein at least one of the base plate, carrier plate, or drive board tolerances is between 0 and 2 microns.

22. The method of claim 20, further comprising:
mounting sets of base bearings to the top surface of the base plate and sets of carrier bearings to the bottom surface of the carrier plate;
assembling a carrier including the carrier plate and the sets of carrier bearings to a base including the base plate and the sets of base bearings;
mounting the actuator armature to the bottom surface of the carrier plate through an actuator armature aperture in the base plate and straddling the position drive board;
coupling a sliding bearing sheet to the actuator armature; and
mounting an actuator stator to the base plate to trap the actuator armature between the actuator stator and the carrier plate.

23. The method of claim 22, further comprising:
setting the sets of carrier bearings into engagement with the sets of base bearings.

24. A method of servicing a nanopositioner produced by the method of claim 22, including removing the actuator stator from the base plate, replacing piezoelectric stack from the actuator stator with a new piezoelectric stack to produce a refurbished actuator stator, and remounting the refurbished actuator stator to the base plate.

25. A method of servicing a nanopositioner produced by the method of claim 22, including removing the actuator stator from the base plate, replacing the actuator stator with a new actuator stator, and remounting the new actuator stator to the base plate.

26. A piezoelectric stack, comprising:
a primary piezoelectric element having primary opposite faces and primary sides extending between the primary opposite faces;
a secondary piezoelectric element having secondary opposite faces and secondary sides extending between the secondary opposite faces; and
a conductive foil disposed between facing faces of the primary and secondary opposite faces of the primary and secondary piezoelectric elements, and having at least one tab extending laterally outwardly with respect to at least one of the primary sides and at least one of the secondary sides.

27. The piezoelectric stack of claim 26, wherein the at least one tab extends a distance beyond the at least one primary side and the at least one secondary side that is greater than a thickness of each of the piezoelectric elements.

28. The piezoelectric stack of claim 26, wherein the primary piezoelectric element includes primary vertices extending between the primary opposite faces and establishing primary corners between the primary sides, and primary bevels extending between the primary opposite faces and being oriented in a first orientation, and wherein the secondary piezoelectric element includes secondary vertices extending between the secondary opposite faces and establishing secondary corners between the secondary sides, and secondary bevels extending between the secondary opposite faces and being oriented in a secondary orientation opposite that of the primary orientation to indicate correct polarity of the piezoelectric elements.

29. A piezoelectric actuator, comprising:
the piezoelectric stack of claim 26; and
a preload plate including:
a mounting face,
a piezo face oppositely disposed from the mounting face,
a piezo pocket in the piezo face carrying the piezoelectric stack and at least partially defined by
a piezo support surface at a bottom of the piezo pocket,
surrounding walls extending away from the piezo support surface, and
semi-circular cutouts at corners of the piezo pocket,
wherein the primary and secondary sides of the primary and secondary piezoelectric elements, are laterally retained by the surrounding walls,
a foil pocket at least partially defined by at least a portion of the piezo pocket and by at least one slot through at least one of the surrounding walls of the piezo pocket, wherein the at least one tab of the conductive foil is carried in the at least one slot.

30. The piezoelectric actuator of claim 29, wherein the preload plate includes beveled sides and wherein the at least one tab of the conductive foil includes bevels corresponding to the beveled sides of the preload plate to assist with correct orientation of the conductive foil with respect to the preload plate.

31. The piezoelectric actuator of claim 29, wherein the preload plate also includes a through hole corresponding to the at least one tab of the conductive foil to facilitate routing a negative lead or wire therethrough.

32. The piezoelectric actuator of claim 29, wherein the preload plate also includes a central through hole extending between the mounting and piezo faces and in communication with the mounting and piezo support surfaces.

33. The piezoelectric actuator of claim 32, wherein the preload plate also includes a channel in the piezo support surface and in communication with the central through hole and extending from the central through hole to a side surface of the preload plate.
